(19) United States
(12) Patent Application Publication
(10) Pub. No.: US 2021/0005647 A1
(43) Pub. Date: Jan. 7, 2021

(54) IMAGE SENSING DEVICE

(71) Applicant: SK hynix Inc., Icheon-si (KR)

(72) Inventors: Pyong Su Kwag, Eumseong-gun (KR); Seung Hoon Sa, Seoul (KR)

(21) Appl. No.: 16/597,618

(22) Filed: Oct. 9, 2019

(30) Foreign Application Priority Data
Jul. 5, 2019 (KR) 10-2019-0081250

(51) Int. Cl. H01L 27/146

(52) U.S. Cl. CPC H01L 27/1463; H01L 27/14605; H01L 27/14614

(57) ABSTRACT

An image sensing device is provided to include a substrate configured to provide pixel regions that are separated from one another by a first isolation structure, a photoelectric conversion element disposed in each of the pixel regions and in a lower region of the substrate, a floating diffusion (FD) region and a first transistor that are disposed in each of the pixel regions and in a first active region positioned in an upper region of the substrate, and a second transistor disposed in each of the pixel regions and in a second active region that is positioned in the upper region of the substrate and separated from the first active region by a second isolation structure. The second isolation structure is disposed to contact a top surface of the substrate and includes an impurity region within a predetermined depth from the top surface of the substrate.

### CROSS-REFERENCE TO RELATED APPLICATION

This patent document claims the priority and benefits of Korean patent application No. 10-2019-0081250, filed on Jul. 5, 2019, which is hereby incorporated in its entirety by reference.

### TECHNICAL FIELD

The technology and implementations disclosed in this patent document relate to an image sensing device.

### BACKGROUND

An image sensing device is a semiconductor device for converting an optical image into electrical signals. Image sensing devices may be classified into CCD (Charge Coupled Device)-based image sensing devices and CMOS (Complementary Metal Oxide Semiconductor)-based image sensing devices.

In recent times, with increasing development of CMOS image sensors, demand for high-quality and high-performance CMOS image sensors is rapidly increasing in various electronic appliances, for example, smartphones, digital cameras, etc. A CMOS image sensor includes a photoelectric conversion element to generate charges from incident light received from outside, and one or more circuits to process electrical signals corresponding to the generated charges.

### SUMMARY

Various embodiments of the disclosed technology relate to an image sensing device which, among other features and benefits, can improve an isolation structure between elements formed in a pixel and improve operational characteristics of the image sensing device.

In accordance with an embodiment of the disclosed technology, an image sensing device may include a substrate configured to provide pixel regions that are separated from one another by a first isolation structure, a photoelectric conversion element disposed in each of the pixel regions and in a lower region of the substrate, a floating diffusion (FD) region and a first transistor that are disposed in each of the pixel regions and in a first active region positioned in an upper region of the substrate, and a second transistor disposed in each of the pixel regions and in a second active region that is positioned in the upper region of the substrate and separated from the first active region by a second isolation structure. The second isolation structure is disposed to contact a top surface of the substrate and include an impurity region in which impurities are implanted to a predetermined depth from the top surface of the substrate.

In accordance with another embodiment of the disclosed technology, an image sensing device may include a pixel region disposed in a substrate and configured to generate an electrical signal in response to incident light, a first active region and a second active region that are disposed in an upper region of the substrate and separated from each other by an impurity region in the substrate, a first transistor disposed in the first active region, and a second transistor disposed in the second active region.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is an example of a block diagram illustrating an image sensor based on some implementations of the disclosed technology.

FIG. 2 is an example of a schematic diagram illustrating a pixel array shown in FIG. 1 based on some implementations of the disclosed technology.

FIG. 3 is another example of a schematic diagram illustrating a pixel array shown in FIG. 1 based on some implementations of the disclosed technology.

FIG. 4 is a plan view illustrating a structure of a unit pixel shown in FIG. 3.

FIG. 5A is a cross-sectional view illustrating a unit pixel taken along the line X1-X1′ shown in FIG. 4.

FIG. 5B is a cross-sectional view illustrating a unit pixel taken along the line X2-X2′ shown in FIG. 4.

FIG. 5C is a cross-sectional view illustrating a unit pixel taken along the line Y-Y′ shown in FIG. 4.

FIG. 6 is a plan view illustrating a structure of a unit pixel shown in FIG. 3.

FIG. 7 is a cross-sectional view illustrating a unit pixel taken along the line X3-X3′ shown in FIG. 6.

FIGS. 8 and 9 are plan views illustrating a unit pixel shown in FIG. 3.

### DETAILED DESCRIPTION

This patent document provides implementations and examples of an image sensing device. Some implementations of the disclosed technology suggest designs of an image sensing device and fabrication techniques for forming the image sensing device to enable to improve optical characteristics and crosstalk characteristics.

As resolution of the CMOS image sensor increases, the size of each pixel contained in the CMOS image sensor is gradually reduced to increase the number of pixels without increasing a chip size. Therefore, interference between the pixels, for example, crosstalk, may occur, which results in reducing the quality and accuracy of an image. In recognition of the issues above, the disclosed technology provides various implementations of an image sensing device, which can reduce or prevent the interference between the pixels and improve optical characteristics of an image.

Reference will now be made in detail to certain embodiments, examples of which are illustrated in the accompanying drawings. Wherever possible, the same reference numbers will be used throughout the drawings to refer to the same or similar parts. In the following description, a detailed description of related known configurations or functions incorporated herein will be omitted to avoid obscuring the subject matter.

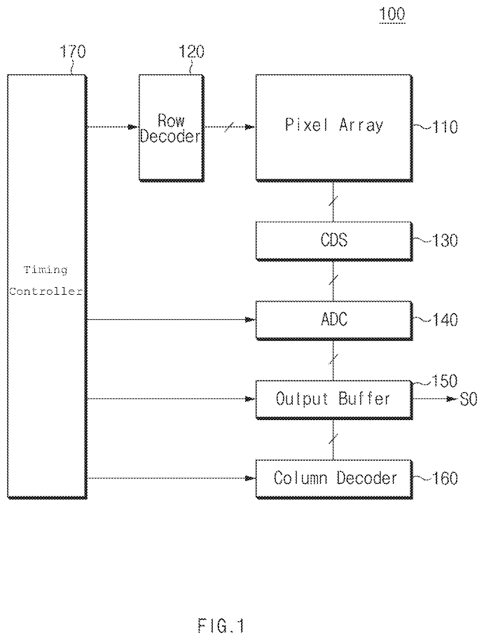

FIG. 1 is a block diagram illustrating an image sensor based on some implementations of the disclosed technology.

Referring to FIG. 1, the image sensor 100 may include a pixel array 110, a row decoder 120, a correlated double sampler (CDS) circuit 130, an analog-to-digital converter (ADC) circuit 140, an output buffer 150, a column decoder 160, and a timing controller 170. In this case, the above-mentioned constituent elements of the image sensor 100 are disclosed only for illustrative purposes, and at least some elements may be added to or omitted from the image sensor 100 as necessary.

The pixel array 110 may be formed in a substrate, and may include a plurality of unit pixels arranged in a two-dimensional (2D) shape. Each unit pixel may include a photosensing pixel to convert an optical signal into an electrical signal. The pixel array 110 may receive a drive signal from the row decoder 120. The photosensing element may include, for example, a photodiode, a photogate, a phototransistor, a photoconductor, or some other photosensing structures capable of generating photocharges. The drive signal may include a row selection signal, a pixel reset signal, a transmission (Tx) signal, and the like. The pixel array 110 may be driven by the drive signal.

The row decoder 120 may drive the pixel array 110 upon receiving a control signal from the timing controller 170. In particular, the row decoder 120 may select at least one row line from among a plurality of row lines of the pixel array 110. In order to select at least one row line from among the plurality of row lines, the row decoder 120 may generate a row selection signal. The row decoder 120 may sequentially enable the pixel reset signal and the transmission (Tx) signal for pixels correlated double sampler (CDS) circuit 130 to the at least one selected row line. Therefore, an analog reference signal and an analog image signal may be generated by each of the pixels contained in the selected row line, such that the analog reference signals and the analog image signals generated by the respective pixels contained in the selected row line can be sequentially transferred to the correlated double sampler (CDS) circuit 130. In this case, the reference signal and the image signal generated by each pixel may be generically called a pixel signal as necessary.

The correlated double sampler (CDS) circuit 130 may sequentially sample and hold the reference signal and the image signal that are transferred from the pixel array 110 to each of the plurality of column lines. That is, the correlated double sampler (CDS) circuit 130 may sample and hold levels of the reference signal and the image signal that correspond to each column of the pixel array 110.

The correlated double sampler (CDS) circuit 130 may transmit a correlated double sampling (CDS) signal corresponding to the reference signal and the image signal for each column to the ADC circuit 140 upon receiving a control signal from the timing controller 170.

The ADC circuit 140 may receive the CDS signal for each column from the CDS circuit 130, may convert the received CDS signal into a digital signal, and may thus output the digital signal. The ADC circuit 140 may perform counting and calculation operations based on the CDS signal for each column and a ramp signal received from the timing controller 170, such that the ADC circuit 140 may generate digital image data from which noise (for example, unique reset noise for each pixel) corresponding to each column is removed.

The ADC circuit 140 may include a plurality of column counters corresponding to respective columns of the pixel array 110, and may convert the CDS signal for each column into a digital signal using the column counters. In accordance with another embodiment, the ADC circuit 140 may include a single global counter, and may convert a CDS signal corresponding to each column into a digital signal using a global code received from the global counter.

The output buffer 150 may receive image data for each column received from the ADC circuit 140, may capture the received image data, and may output the captured image data. The output buffer 150 may temporarily store image data that is output from the ADC circuit 140 upon receiving a control signal from the timing controller 170. The output buffer 150 may operate as an interface configured to compensate for a difference in transmission (Tx) speed (or in processing speed) between the image sensor 100 and another device coupled to the image sensor 100.

The column decoder 160 may select a column of the output buffer 150 upon receiving a control signal from the timing controller 170, and may sequentially output the temporarily stored image data to the selected column of the output buffer 150. In more detail, the column decoder 160 may receive an address signal from the timing controller 170, may generate a column selection signal based on the received address signal, and may select a column of the output buffer 160, such that the column decoder 160 may control image data to be output as an output signal SO from the selected column of the output buffer 160.

The timing controller 170 may control the row decoder 120, the ADC circuit 140, the output buffer 150, and the column decoder 160.

The timing controller 170 may transmit a clock signal needed for the constituent elements of the image sensor 100, a control signal needed for timing control, and address signals needed for selection of a row or column to the row decoder 120, the column decoder 160, the ADC circuit 140, and the output buffer 150. In accordance with the embodiment, the timing controller 170 may include a logic control circuit, a phase locked loop (PLL) circuit, a timing control circuit, a communication interface circuit, etc.

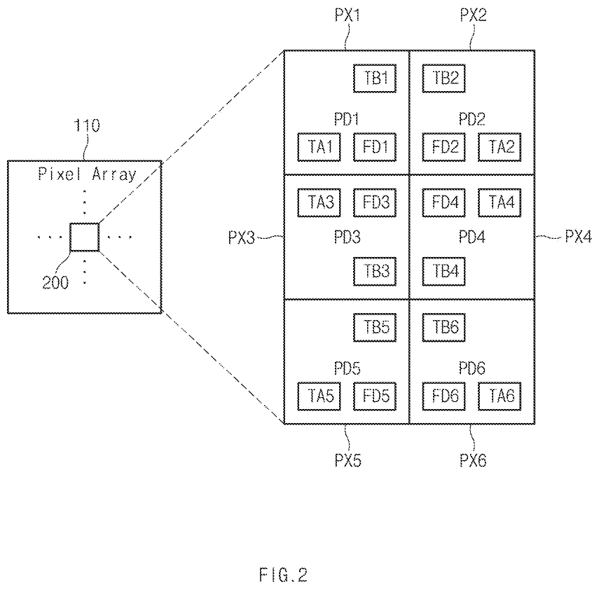

FIG. 2 is an example of a schematic diagram illustrating the pixel array shown in FIG. 1.

Referring to FIG. 2, the pixel array 110 may illustrate an example of the pixel array shown in FIG. 1. The pixel array 110 may have a specific structure in which each pixel group 200 is repeatedly arranged in a matrix shape including rows and columns.

A detailed schematic diagram of each pixel group 200 is shown in the right side of FIG. 2. In the example, each pixel group 200 may include 6 unit pixels PX1 to PX6.

Each of the unit pixels PX1 to PX6 may be an isolated pixel that is physically isolated from contiguous or adjacent unit pixels. Therefore, each of the unit pixels PX1 to PX6 is unable to share a photoelectric conversion element PD, a floating diffusion (FD) region, or a transistor with contiguous or adjacent unit pixels. For example, each of the unit pixels PX1 to PX6 may include its own photoelectric conversion element PD, floating diffusion (FD) region, or transistor.

In accordance with the embodiment, each of the unit pixels PX1 to PX6 may be an isolated pixel, and may be physically isolated from the contiguous or adjacent unit pixels by a trench-shaped isolation structure (e.g., a Shallow Trench Isolation (STI) structure or a Deep Trench Isolation (DTI) structure). In this case, the trench-shaped isolation structure may refer to an isolation structure in which a substrate is etched to a predetermined depth and an insulation material is buried in the etched region. In the present embodiment, the trench-shaped isolation structure may include a stacked structure including the STI structure and the DTI structure.

Each of the unit pixels PX1 to PX6 may include a Back Side Illumination (BSI) structure or a Front Side Illumination (FSI) structure.

In some implementations, elements contained in different unit pixels may be electrically connected through, for example, a metal line.

Each of the unit pixels PX1 to PX6 may include a single photoelectric conversion element (PD), a single floating diffusion (FD) region, and two pixel transistors TA and TB. For example, the first unit pixel PX1 may include a single photoelectric conversion element PD1, a single floating diffusion (FD) region FD1, and two pixel transistors TA1 and TB1.

In some implementations, the pixel transistor TA1 may be a transfer transistor (or a transmission transistor) configured to transmit photocharges generated by the photoelectric conversion element PD1 to the floating diffusion (FD) region FD1. The pixel transistor TB1 may be any one of drive transistors. For example, the pixel transistor TB1 may be any one of a reset transistor configured to initialize the floating diffusion (FD) region in response to the reset signal, a source follower transistor configured to generate a pixel signal corresponding to photocharges of the floating diffusion (FD) region, or a selection transistor configured to output a pixel signal to the column line according to a selection signal.

In some implementations, in each of the unit pixels PX1 to PX6, active regions may be formed in which the floating diffusion (FD) region, the pixel transistors TA and TB, and a tap region for applying a bias voltage to a well region of the substrate are formed. The active regions may be isolated by using an impurity region (e.g., a junction isolation structure) instead of a trench isolation structure formed by etching of the substrate. The impurity region may be formed by implanting impurities into the substrate. Thus, a trench structure for the device isolation may be not formed in each of the unit pixels PX1 to PX6.

Each of the photoelectric conversion elements PD1 to PD6 respectively contained in the unit pixels PX1 to PX6 may be formed in a lower region (or a lower portion) of the substrate of the corresponding unit pixel. In some implementations, in order to increase light reception efficiency, the photoelectric conversion elements PD1 to PD6 may be formed in an entire area of the lower region of the substrate.

In the sections that follow, it will be discussed in detail how the floating diffusion (FD) regions respectively contained in the unit pixels PX1 to PX6, and the transistors respectively contained in the unit pixels PX1 to PX6, are arranged.

FIG. 2 illustrates that the floating diffusion (FD) region and the transistors TA and TB are disposed in three different regions of four regions that are formed by equally dividing each unit pixel, e.g., in a vertical direction and a horizontal direction. It should be noted that such arrangement is one example only and that the floating diffusion (FD) region and the transistors TA and TB can be arranged in other various manners. For example, at least one of the transistors can be formed to occupy two or more regions among four regions that are obtained by equally dividing each unit pixel.

The arrangement of the floating diffusion (FD) regions will be first discussed. The four floating diffusion (FD) regions FD1 to FD4, which are arranged in the four unit pixels PX1 to PX4, respectively, may be positioned as close as possible. For example, the floating diffusion (FD) regions FD1 to FD4, which are arranged in the four unit pixels PX1 to PX4, respectively, may be located around corner regions of the corresponding unit pixels where the four unit pixels meet.

The floating diffusion (FD) regions FD1 to FD4 may be coupled to one another through a metal line (not shown), thereby forming a single node. The length of the metal line depends on the arrangement of the floating diffusion (FD) regions connected through the metal line. The above arrangement that the four floating diffusion (FD) regions are positioned as close as possible to one another can minimize the length of the metal line through which the floating diffusion (FD) regions FD1˜FD4 are interconnected.

In the example of FIG. 2, the floating diffusion (FD) regions and the transistors have a symmetrical arrangement with respect to a boundary between two adjacent unit pixels. For example, the floating diffusion (FD) regions and the transistors of the unit pixels that are arranged adjacent to each other in a first direction (e.g., a horizontal direction in FIG. 2) and a second direction (e.g., a vertical direction in FIG. 2) perpendicular to the first direction may be arranged symmetrically to each other with respect to a boundary between the two adjacent unit pixels. For example, in the respective unit pixels PX1 to PX6, each of the transfer transistors TA1 to TA6 may be arranged adjacent to a corresponding floating diffusion (FD) region FD1 to FD6 in the first direction. In addition, each of the drive transistors TB1 to TB6 may be arranged adjacent to a corresponding floating diffusion (FD) regions FD1 to FD6 in the second direction.

For example, in the four unit pixels PX1 to PX4 in which the floating diffusion (FD) regions FD1 to FD4 are commonly coupled to each other, the transistor TA1 of the left unit pixel PX1 may be arranged at one side, e.g., the left side in FIG. 2, of the floating diffusion (FD) region FD1, and the transistor TA3 of the left unit pixel PX3 may be arranged at one side, e.g., the left side in FIG. 2, of the floating diffusion (FD) region FD3. The transfer transistor TA2 of the right unit pixel PX2 may be arranged at one side, e.g., the right side in FIG. 2, of the floating diffusion (FD) region FD2, and the transfer transistor TA4 of the right unit pixel PX4 may be arranged at one side, e.g., the right side in FIG. 2, of the floating diffusion (FD) region FD4.

In the four unit pixels PX1 to PX4 in which the floating diffusion (FD) regions FD1 to FD4 are coupled to each other, the drive transistor TB1 of the upper unit pixel PX1 may be arranged at one side, e.g., the upper side in FIG. 2, of the floating diffusion (FD) region FD1, and the drive transistor TB2 of the upper unit pixel PX2 may be arranged at one side, e.g., the upper side in FIG. 2, of the floating diffusion (FD) region FD2. The drive transistor TB3 of the lower unit pixel PX3 may be arranged at one side, e.g., the lower side, of the floating diffusion (FD) region FD3, and the drive transistor TB4 of the lower unit pixel PX4 may be arranged at one side, e.g., the lower side, of the floating diffusion (FD) region FD4.

The floating diffusion and the transistors that are included in the unit pixels PX5 and PX6 may have a same arrangement as those in the unit pixels PX1 and PX2. Thus, the floating diffusion (FD) regions FD5 and FD6 and the transistors TA5, TA6, TB5, and TB6 may be arranged in the unit pixels PX5 and PX6 in the same manner that the floating diffusion (FD) regions FD1 and FD2 and the transistors TA1, TA2, TB1, and TB2 are arranged in the unit pixels PX1 and PX2.

Therefore, in the four unit pixels including PX3 to PX6, instead of the floating diffusion (FD) regions, the drive transistors TB3 to TB6 are arranged as close as possible to each other.

Thus, in the pixel group 200 including 6 unit pixels PX1 to PX6 having a 3×2 array structure including 3 rows and 2 columns, the floating diffusion (FD) regions FD1 to FD4 of the four unit pixels PX1 to PX4 having a 2×2 array structure may be arranged as close as possible to each other, and the drive transistors TB3 to TB6 of the four unit pixels PX3 to PX6 having a 2×2 array structure may be arranged as close as possible to each other.

The pixel array 110 may be designed in a manner that the pixel group 200 is repeatedly arranged not only in the first direction, but also in the second direction. Although FIG. 2 illustrates an exemplary case in which the pixel group 200 includes the unit pixels PX1 to PX6 having the 3×2 array structure, other implementations are also possible, For example, 6 unit pixels can be having 2×3 array structure, and the floating diffusion (FD) regions and the transistors can be arranged based on the arrangement explained above with regard to FIG. 2.

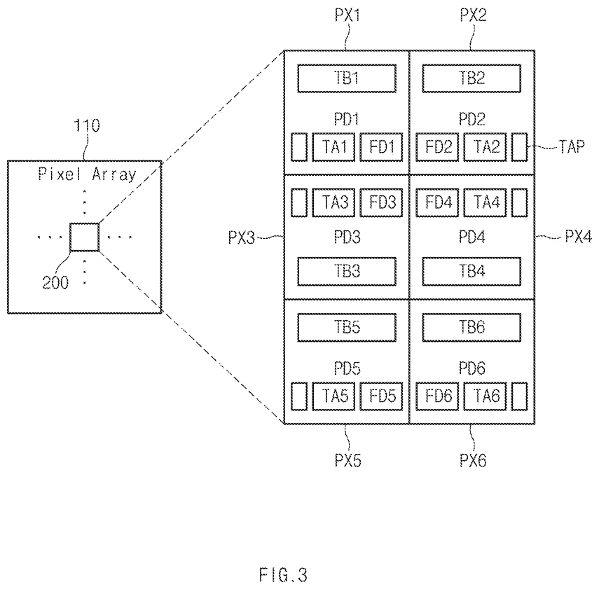

FIG. 3 is another example of a schematic diagram illustrating a pixel array shown in FIG. 1.

Referring to FIG. 3, each of the drive transistors TB1 to TB6, which are arranged in the unit pixels PX1 to PX6, respectively, may extend in the first direction. Thus, the drive transistors TB1 to TB6 may have a size greater than those in FIG. 2.

In the unit pixels PX1 to PX6, the transfer transistors TA1 to TA6 are arranged adjacent to the floating diffusion (FD) regions FD1 to FD6 in the first direction (e.g., a horizontal direction in FIG. 3). No other elements than the drive transistors TB1 to TB6 are arranged adjacent to each other in the first direction in the unit pixels PX1 to PX6. Thus, the drive transistors TB1 to TB6 can extend as long as possible along the first direction within the corresponding unit pixels PX1 to PX6.

A tap region TAP for applying a bias voltage to a well region of the substrate may be formed at one side of each of the transfer transistors TA1 to TA6. Each tap region TAP may include an impurity region in which P-type (P+) impurities are implanted in the same manner as in the well region.

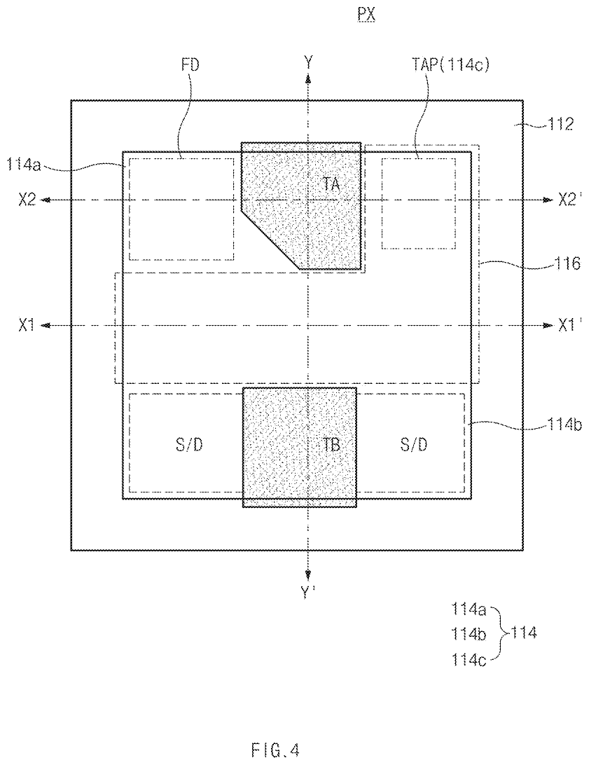

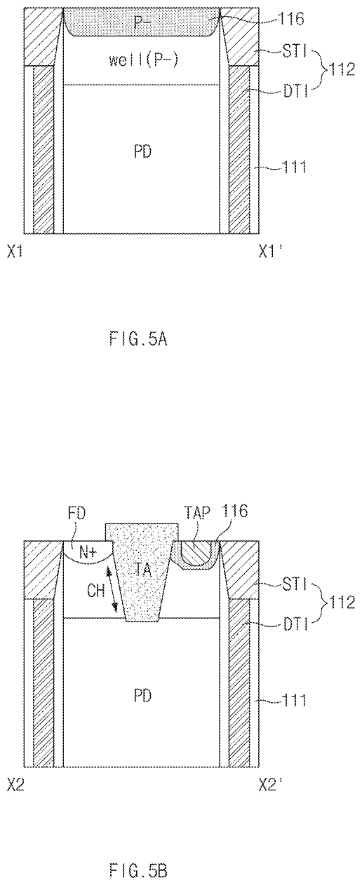

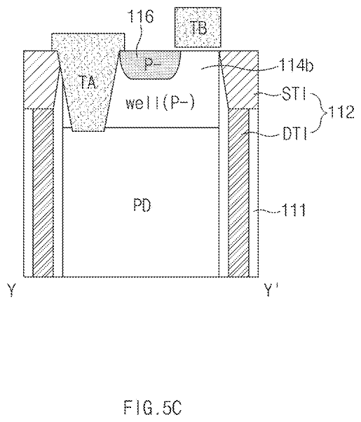

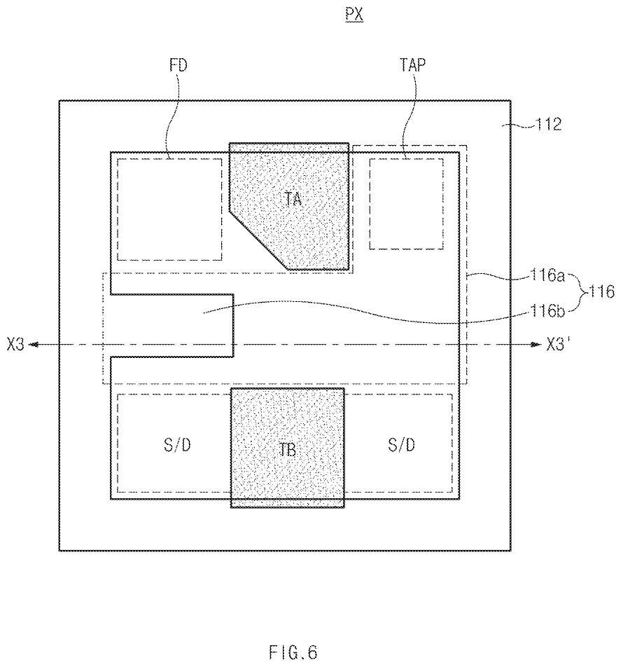

FIG. 4 is a plan view illustrating a structure of any one of unit pixels shown in FIG. 3. FIG. 5A is a cross-sectional view illustrating the unit pixel taken along the line X1-X1′ shown in FIG. 4 based on some implementations of the disclosed technology. FIG. 5B is a cross-sectional view illustrating the unit pixel taken along the line X2-X2′ shown in FIG. 4 based on some implementations of the disclosed technology. FIG. 5C is a cross-sectional view illustrating the unit pixel taken along the line Y-Y′ shown in FIG. 4 based on some implementations of the disclosed technology.

Referring to FIGS. 4, 5A, 5B, and 5C, the unit pixel PX may be isolated from other unit pixels by a first isolation structure 112.

A first isolation structure 112 may include a trench formed by etching a substrate 1. For example, the first isolation structure 112 may include a stacked structure of the STI structure and the DTI structure. In a vertical view, the first device isolation structure 112 may pass through the substrate 1. In a plan view, the first isolation structure 112 may have a band shape that surrounds the unit pixel PX.

Each unit pixel PX isolated by the first isolation structure 112 may include a photoelectric conversion element PD, a floating diffusion (FD) region, a transfer transistor TA, a drive transistor TB, and a tap region TAP. The unit pixel PX as shown in FIGS. 4 and 5A to 5C may correspond to any one of the unit pixels PX1 to PX6 shown in FIGS. 2 and 3. Thus, the transfer transistor TA may correspond to any one of the transfer transistors TA1 to TA6, and the drive transistor TB may correspond to any one of the drive transistors TB1 to TB6.

As can be seen from FIG. 4, each reference number of each of the transistors TA and TB is illustrated in a gate of the corresponding transistor.

The photoelectric conversion element PD may generate photocharges by converting an incident light signal into an electrical signal. The photoelectric conversion element PD may be formed in a lower region of the substrate 111 in the unit pixel PX (see FIGS. 5A and 5B). In order to increase light reception efficiency, the size of the photoelectric conversion element PD needs to increase as well. Thus, the photoelectric conversion element PD may be formed to occupy an area as large as possible, wherein the area is located in the lower region of the substrate 111. For example, the photoelectric conversion element PD may be formed in the lower region of the substrate 111 while vertically overlapping with an active region 114 and an isolation structure 116 (see FIGS. 5A and 5B).

The floating diffusion (FD) region, the transfer transistor TA, the drive transistor TB, and the tap region TAP that are formed in the unit pixel PX may be formed in active regions 114a, 114b, and 114c defined by the second isolation structure 116 (see FIGS. 4, 5A and 5B). For example, in the upper region of the substrate 111, the second isolation structure 116 may isolate the first active region 114a, the second active region 114b, and the third active region 114c from one another. In this case, the floating diffusion (FD) region and the transfer transistor TA are formed at the first active region 114a, the drive transistor TB is formed at the second active region 114b, and the tap region TAP is formed at the third active region 114c.

The second isolation structure 116 may be or include an impurity region formed by implanting P-type (P−) impurities into the upper region of the substrate 111. For example, the second isolation structure 116 may be in contact with a top surface of the substrate 111, and may be or include an impurity region in which impurities are implanted to a predetermined depth from the top surface of the substrate 111. The second isolation structure 116 may include a junction isolation structure formed using impurities implanted into the upper region of the substrate 111. The junction isolation structure is different from the trench isolation structure such as the STI structure or the DTI structure, which is formed by formed by etching some regions of the upper region of the substrate 111 such as the STI or DTI structure.

The transfer transistor TA may be or include a transistor configured to use the photoelectric conversion element PD and the floating diffusion (FD) region as source/drain regions, and may transmit photocharges generated by the photoelectric conversion element PD to the floating diffusion (FD) region in response to a transmission (Tx) signal. The transfer transistor TA may include a vertical gate that couples the photoelectric conversion element PD formed in the lower region of the substrate 111 to the floating diffusion (FD) region formed in the upper region of the substrate 111 through a vertical channel CH.

The drive transistor TB may be any one of a reset transistor, a source follower transistor, or a selection transistor. The reset transistor may initialize the floating diffusion (FD) region in response to the reset signal. The source follower transistor may generate a pixel signal corresponding to photocharges stored in the floating diffusion (FD) region. The selection transistor may output the pixel signal to the column line in response to the selection signal.

In the isolated pixel in which the photoelectric conversion element PD is formed in a lower region of the isolated pixel and photocharges are transferred from the photoelectric conversion element PD to the floating diffusion (FD) region using a vertical transfer transistor in which the vertical channel is formed, when a trench structure is present in the substrate 1, the trench structure may cause a dark current and a hot pixel.

Therefore, some embodiments of the disclosed technology may suggest not using the trench isolation structure in the unit pixel. As discussed above, in the embodiments of the disclosed technology, the active region 114 are provided using the junction isolation structure 116 formed by implanting impurities into the substrate 111, thereby minimizing a dark current and the number of hot pixels.

The tap region TAP may be a region for applying a bias voltage to the well region of the substrate, and may include a P-type impurity region that is identical to the well region and is formed by implantation of high-density P-type (P+) impurities. The tap region TAP may be formed in the second isolation structure 116.

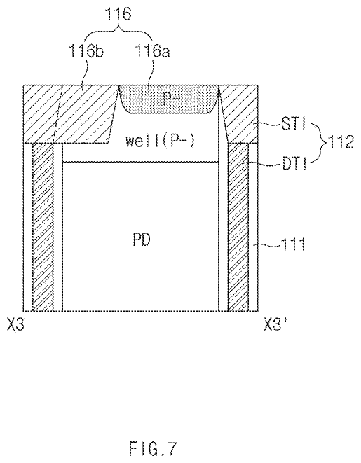

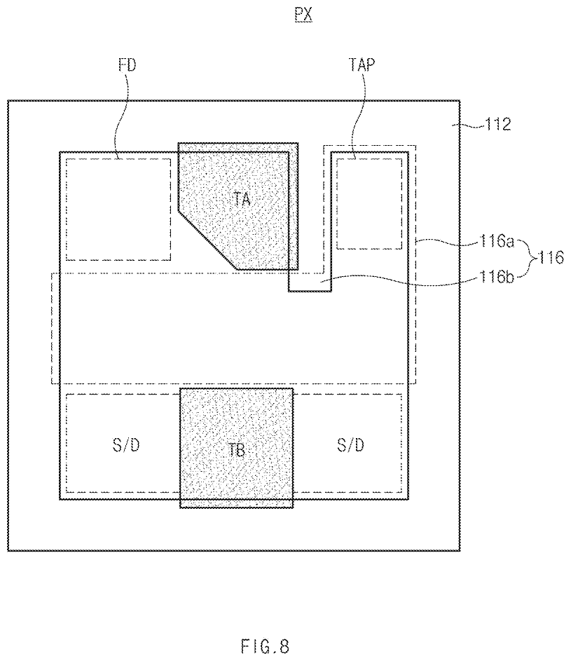

FIG. 6 is a plan view illustrating a structure of any one of unit pixels shown in FIG. 3. FIG. 7 is a cross-sectional view illustrating the unit pixel taken along the line X3-X3′ shown in FIG. 6.

Referring to FIGS. 6 and 7, the second isolation structure 116 may partially include the STI structure 116b.

For example, the STI structure 116b may be formed between the floating diffusion (FD) region and source/drain regions S/D of the drive transistor TB.

Unlike the implementation as shown in FIG. 4 in which the second isolation structure 116 is formed using the impurity region, the disclosed technology is not limited thereto. For example, the implementation as shown in FIGS. 6 and 7 shows that the STI structure is partially formed in a region that leakage can occur among the plurality of elements FD, TA, TB, and TAB.

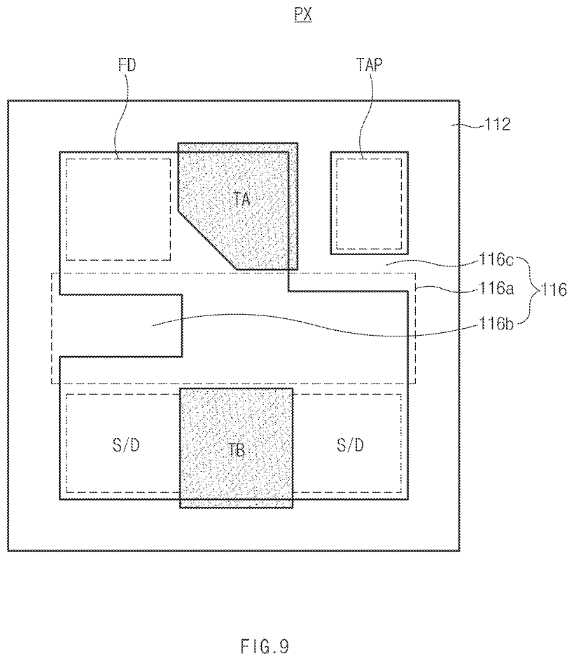

FIGS. 8 and 9 are plan views illustrating any one of unit pixels shown in FIG. 3.

Referring to FIG. 8, the STI structure 116b of the second isolation structure 116 may be formed between the tap region TAP and the gate terminal of the transfer transistor TA.

Alternatively, as can be seen from FIG. 9, the STI structure 116b is formed between the floating diffusion (FD) region and source/drain regions S/D of the drive transistor TB and the STI structure 116c may be formed to surround the tap region TAP in a manner that the tap region TAP can be completely isolated.

FIGS. 6 to 9 illustrate exemplary embodiments. In FIGS. 6 to 9, the STI structure may be optionally formed in any region in which there is a high possibility of leakage.

As is apparent from the above description, the image sensing device according to the embodiments of the disclosed technology can improve operational characteristics thereof. Specifically, the image sensing device according to the embodiments of the disclosed technology can minimize the number of dark current occurrences and the number of hot pixel occurrences.

Although a number of illustrative embodiments have been described, it should be understood that numerous other modifications and embodiments can be devised by those skilled in the art based on the what is described and illustrated in this patent document.

What is claimed is:

1. An image sensing device, comprising:
a substrate configured to provide pixel regions that are separated from one another by a first isolation structure;
a photoelectric conversion element disposed in each of the pixel regions and in a lower region of the substrate;
a floating diffusion (FD) region and a first transistor that are disposed in each of the pixel regions and in a first active region positioned in an upper region of the substrate; and
a second transistor disposed in each of the pixel regions and in a second active region that is positioned in the upper region of the substrate and separated from the first active region by a second isolation structure,
wherein the second isolation structure is disposed to contact a top surface of the substrate and includes an impurity region within a predetermined depth from the top surface of the substrate.

2. The image sensing device according to claim 1, wherein the first isolation structure includes a trench isolation structure including insulation material in a trench formed by etching of the substrate.

3. The image sensing device according to claim 1, wherein the first isolation structure passes through the substrate, and has a shape that surrounds each of the pixel regions.

4. The image sensing device according to claim 1, wherein the second isolation structure includes P-type (P−) impurities.

5. The image sensing device according to claim 1, wherein the first transistor includes:
a transfer transistor configured to transmit photocharges generated by the photoelectric conversion element to the floating diffusion (FD) region.

6. The image sensing device according to claim 5, wherein the second transistor includes at least one of:
a reset transistor configured to initialize the floating diffusion (FD) region in response to a reset signal;
a source follower transistor configured to generate a pixel signal corresponding to photocharges stored in the floating diffusion (FD) region; or
a selection transistor configured to output the pixel signal to a column line in response to a selection signal.

7. The image sensing device according to claim 1, further comprising:
a tap region disposed in each of the pixel regions and configured to be isolated from the first active region and the second active region by the second isolation structure.

8. The image sensing device according to claim 7, wherein:
the tap region is located adjacent to the first active region in a first direction; and
the second active region is located adjacent to the first active region in a second direction perpendicular to the first direction.

9. The image sensing device according to claim 1, wherein the pixel regions include first to sixth pixels which are arranged in a matrix structure including 3 rows and 2 columns to form a pixel group,
wherein, in the pixel group, the floating diffusion (FD) regions in the first to fourth pixel regions are arranged as close as possible to one another and the second transistors in the third to sixth unit pixels are arranged as close as possible to one another.

10. The image sensing device according to claim 1, wherein some of the pixel regions include floating diffusion (FD) regions that are located around corner regions of each of the some of the pixel regions.

11. The image sensing device according to claim 1, wherein:
floating diffusion (FD) regions, first transistors, and second transistors are arranged symmetrical with respect to a boundary between two adjacent pixel regions that are adjacent to each other in a first direction or in a second direction perpendicular to the first direction.

12. The image sensing device according to claim 1, wherein the first transistor includes:
a vertical gate that couples the photoelectric conversion element to the floating diffusion (FD) region through a vertical channel.

13. The image sensing device according to claim 1, wherein the second isolation structure further includes a shallow trench isolation (STI) structure.

14. The image sensing device according to claim 1, wherein the first active region, the second active region, and the second isolation structure are located over the photoelectric conversion element.

15. An image sensing device, comprising:
a pixel region disposed in a substrate and configured to generate an electrical signal in response to incident light;
a first active region and a second active region that are disposed in an upper region of the substrate and separated from each other by an impurity region in the substrate;
a first transistor disposed in the first active region; and
a second transistor disposed in the second active region.

16. The image sensing device according to claim 15, wherein the first transistor includes:
a transfer transistor configured to transmit photocharges generated by the photoelectric conversion element to the floating diffusion (FD) region.

17. The image sensing device according to claim 16, wherein the second transistor includes at least one of:
a reset transistor configured to initialize the floating diffusion (FD) region in response to a reset signal;
a source follower transistor configured to generate a pixel signal corresponding to the photocharges stored in the floating diffusion (FD) region; or
a selection transistor configured to output the pixel signal to a column line in response to a selection signal.

18. The image sensing device according to claim 15, wherein:
the impurity region includes P-type (P−) impurities and is disposed in the upper region of the substrate, the impurity region having a predetermined depth.

19. The image sensing device according to claim 15, wherein the pixel region is surrounded by a trench isolation structure and separated from another pixel region.

20. The image sensing device according to claim 18, wherein the impurity region is disposed without overlapping a trench isolation structure that passes through the substrate.
